(19) United States
(12) Patent Application Publication
(10) Pub. No.: US 2020/0258976 A1
(43) Pub. Date: Aug. 13, 2020

(54) SEMICONDUCTOR DEVICE

(71) Applicant: Samsung Electronics Co., Ltd., Suwon-si (KR)

(72) Inventors: Jinho PARK, Suwon-si (KR); Yongseung BANG, Suwon-si (KR); Jeong Hoon AHN, Suwon-si (KR)

(73) Assignee: Samsung Electronics Co., Ltd., Suwon-si (KR)

(21) Appl. No.: 16/544,088

(22) Filed: Aug. 19, 2019

(30) Foreign Application Priority Data
Feb. 11, 2019 (KR) 10-2019-0015421

(51) Int. Cl. H01L 49/02

(52) U.S. Cl. CPC H01L 28/60; H01L 28/56

(57) ABSTRACT

A semiconductor device includes a first lower pad and a second lower pad on a substrate, a first electrode being in contact with a top surface of the first lower pad, a second electrode disposed on the first electrode and being in contact with a top surface of the second lower pad, a dielectric layer between the first electrode and the second electrode, and a third electrode on the second electrode.

### CROSS-REFERENCE TO RELATED APPLICATION

This U.S. non-provisional patent application claims priority under 35 U.S.C. § 119 to Korean Patent Application No. 10-2019-0015421, filed on Feb. 11, 2019, in the Korean Intellectual Property Office, the disclosure of which is hereby incorporated by reference in its entirety.

### BACKGROUND

Example embodiments of the inventive concepts relate to a semiconductor device and, more particularly, to a semiconductor device including a metal-insulator-metal (MIM) capacitor.

Typically, as the integration density of a semiconductor device (e.g., a dynamic random access memory (DRAM) device) increases, an area of a unit cell may decrease. Thus, an area occupied by a capacitor may also decrease. However, the minimum capacitance should be secured in the capacitor even though the area of the capacitor is reduced.

When a thickness of a dielectric layer is reduced to increase the capacitance, a leakage current may occur in the capacitor. Thus, a dielectric layer having a high dielectric constant (e.g., a high-k dielectric layer) may be used in the capacitor. However, when the high-k dielectric layer is used in the capacitor, a low-k dielectric layer may be formed between the high-k dielectric layer and a poly-silicon layer used as an upper electrode. Thus, a desired capacitance may not be obtained. Accordingly, a metal-insulator-metal (MIM) capacitor may be used instead of a metal-insulator-semiconductor (MIS) capacitor.

### SUMMARY

Example embodiments of the inventive concepts may provide a semiconductor device capable of simplifying manufacturing processes.

Example embodiments of the inventive concepts may also provide a semiconductor device capable of improving electrical characteristics.

According to some example embodiments, a semiconductor device may include a first lower pad and a second lower pad on a substrate, a first electrode in contact with a top surface of the first lower pad, a second electrode on the first electrode, the second electrode in contact with a top surface of the second lower pad, a dielectric layer between the first electrode and the second electrode, and a third electrode on the second electrode.

According to some example embodiments, a semiconductor device may include a first lower pad and a second lower pad on a substrate, a first electrode on the first lower pad and connected to the first lower pad, a second electrode on the first electrode and connected to a top surface of the second lower pad, a first dielectric layer between the first electrode and the second electrode, a second dielectric layer on the second electrode, and a third electrode on the second dielectric layer and in contact with a top surface of the first electrode.

According to some example embodiments, a semiconductor device may include a first pad and a second pad on a substrate, a first insulating layer on the first pad and the second pad, a first electrode on the first insulating layer, a first through-via penetrating the first insulating layer and electrically connecting a bottom surface of the first electrode and a top surface of the first pad, a second electrode on the first electrode, a second through-via penetrating the first insulating layer and electrically connecting a bottom surface of the second electrode and a top surface of the second pad, a first dielectric layer between the first electrode and the second electrode, a second dielectric layer on the second electrode, and a third electrode on the second dielectric layer.

### BRIEF DESCRIPTION OF THE DRAWINGS

The inventive concepts will become more apparent in view of the attached drawings and accompanying detailed description.

FIG. 1 is a cross-sectional view illustrating a semiconductor device according to some example embodiments of the inventive concepts.

FIG. 2 is a cross-sectional view illustrating a semiconductor device according to some example embodiments of the inventive concepts.

FIG. 3 is a cross-sectional view illustrating a semiconductor device according to some example embodiments of the inventive concepts.

FIG. 4 is a cross-sectional view illustrating a semiconductor device according to some example embodiments of the inventive concepts.

FIG. 5 is a cross-sectional view illustrating a semiconductor device according to some example embodiments of the inventive concepts.

FIG. 6 is a cross-sectional view illustrating a semiconductor device according to some example embodiments of the inventive concepts.

FIGS. 7A to 7E are cross-sectional views illustrating a method of manufacturing a semiconductor device, according to some example embodiments of the inventive concepts.

### DETAILED DESCRIPTION

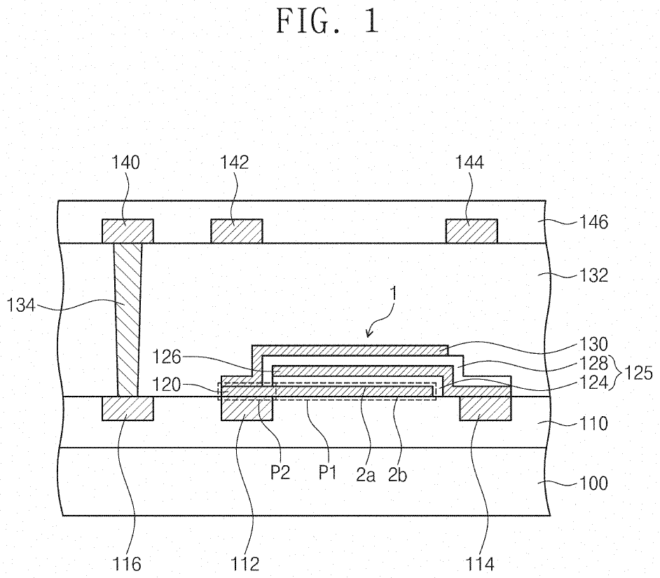

FIG. 1 is a cross-sectional view illustrating a semiconductor device according to some example embodiments of the inventive concepts.

Referring to FIG. 1, a first interlayer insulating layer 110 may be disposed on a substrate 100. The substrate 100 may be a single-crystalline silicon wafer or a silicon-on-insulator (SOI) substrate. The first interlayer insulating layer 110 may cover a top surface of the substrate 100. The first interlayer insulating layer 110 may include an insulating material such as a silicon oxide layer, a silicon nitride layer, and/or a silicon oxynitride layer. A first lower pad 112, a second lower pad 114 and/or a third lower pad 116 may be disposed in the first interlayer insulating layer 110. The first lower pad 112, the second lower pad 114 and/or the third lower pad 116 may be spaced apart from each other. The first lower pad 112 may be disposed between the second lower pad 114 and the third lower pad 116. Top surfaces of the first to third lower pads 112, 114 and 116 may be exposed by the first interlayer insulating layer 110. The first to third lower pads 112, 114 and 116 may include a metal material (e.g., copper, aluminum, and/or tungsten).

A first electrode 120 may be disposed on the first interlayer insulating layer 110. The first electrode 120 may be in physical contact with the first lower pad 112. For example, the first electrode 120 may be in contact with the top surface of the first lower pad 112. The first electrode 120 may be spaced apart from the second lower pad 114 and/or the third lower pad 116. The top surfaces of the second and/or third lower pads 114 and 116 may be exposed by the first electrode 120. For example, the first electrode 120 may include at least one of TaN, Ta, Al, Ti, TiN, TaSiN, WN, and/or WSiN. A first dielectric portion 124 may be disposed on the first electrode 120. The first dielectric portion 124 may cover a top surface 2a of a first portion P1 of the first electrode 120 and/or a sidewall of the first electrode 120. The first dielectric portion 124 may expose a top surface of a second portion P2 of the first electrode 120 and/or the top surface of the second lower pad 114. For example, the first dielectric portion 124 may include at least one of Si₃N₄, Ta₂O₅, Al₂O₃, and/or ZrO₂.

A second electrode 126 may be disposed on the first dielectric portion 124. The second electrode 126 may cover a top surface and/or a sidewall of the first dielectric portion 124 and/or the top surface of the second lower pad 114. The second electrode 126 may be in contact with the top surface of the second lower pad 114. The second electrode 126 may be spaced apart from the first electrode 120. In other words, the second electrode 126 may not be electrically connected to the first electrode 120. The second electrode 126 may expose the top surface of the second portion P2 of the first electrode 120, which is exposed by the first dielectric portion 124. A portion of a bottom surface of the second electrode 126 may be substantially coplanar with a bottom surface of the first electrode 120. For example, the second electrode 126 may include at least one of TaN, Ta, Al, Ti, TiN, TaSiN, WN, and/or WSiN.

A second dielectric portion 128 may be disposed on the second electrode 126. The second dielectric portion 128 may cover a top surface and/or sidewalls of the second electrode 126 and/or a sidewall of the first dielectric portion 124. The second dielectric portion 128 may completely cover the top surface of the second electrode 126. The second dielectric portion 128 may be in contact with an end of the first dielectric portion 124. Thus, the first dielectric portion 124 may be connected to the second dielectric portion 128. The second dielectric portion 128 may expose the top surface of the second portion P2 of the first electrode 120, which is exposed by the first dielectric portion 124. For example, the second dielectric portion 128 may include at least one of Si₃N₄, Ta₂O₅, Al₂O₃, and/or ZrO₂. The first dielectric portion 124 and/or the second dielectric portion 128 may be defined as a dielectric layer 125.

A third electrode 130 may be disposed on the second dielectric portion 128. The third electrode 130 may cover a top surface and/or a sidewall of the second dielectric portion 128, and/or the top surface of the second portion P2 of the first electrode 120 exposed by the first and/or second dielectric portions 124 and 128. The third electrode 130 may be in contact with the top surface of the second portion P2 of the first electrode 120. The third electrode 130 may be connected to the top surface of the second portion P2 of the first electrode 120. Thus, the first electrode 120 and the third electrode 130 may be connected to each other. For example, the third electrode 130 may include at least one of TaN, Ta, Al, Ti, TiN, TaSiN, WN, and/or WSiN. In some example embodiments, the first to third electrodes 120, 126 and 130 and/or the dielectric layer 125 may constitute a capacitor 1.

A second interlayer insulating layer 132 may be disposed on the first interlayer insulating layer 110. The second interlayer insulating layer 132 may cover the capacitor 1. For example, the second interlayer insulating layer 132 may cover the first electrode 120, the second electrode 126, the second dielectric portion 128, the third electrode 130, and/or the third lower pad 116. The second interlayer insulating layer 132 may include an insulating material such as a silicon oxide layer, a silicon nitride layer, and/or a silicon oxynitride layer.

A through-via 134 may be disposed in the second interlayer insulating layer 132. The through-via 134 may penetrate the second interlayer insulating layer 132 and may be in contact with the third lower pad 116. The through-via 134 may include a conductive material (e.g., tungsten (W), copper (Cu), and/or aluminum (Al)).

A first upper pad 140, a second upper pad 142 and/or a third upper pad 144 may be disposed on the second interlayer insulating layer 132. The first upper pad 140 may be disposed on the through-via 134 and may be electrically connected to the through-via 134. In some example embodiments, the first lower pad 112 electrically connected to the first and/or third electrodes 120 and 130 may be electrically connected to the first upper pad 140 through the third lower pad 116 and/or the through-via 134. The second lower pad 114 may be electrically connected to one of the second and third upper pads 142 and 144 through a through-via (not shown). A third interlayer insulating layer 146 may be disposed on the second interlayer insulating layer 132. The third interlayer insulating layer 146 may cover the first to third upper pads 140, 142 and 144. The third interlayer insulating layer 146 may include an insulating material such as a silicon nitride layer, a silicon oxide layer, and/or a silicon oxynitride layer.

According to some example embodiments of the inventive concepts, the first electrode 120 may be in direct contact with the first lower pad 112, and/or the second electrode 126 may be in direct contact with the second lower pad 114. Thus, it is possible to omit a process of forming through-vias for connecting the first electrode 120 to the first lower pad 112 and/or connecting the second electrode 126 to the second lower pad 114. As a result, processes of manufacturing the semiconductor device may be simplified. In addition, since the first and/or second electrodes 120 and 126 are in direct contact with the first and/or second lower pads 112 and 114, respectively, resistances may be reduced. As a result, electrical characteristics of the semiconductor device may be improved.

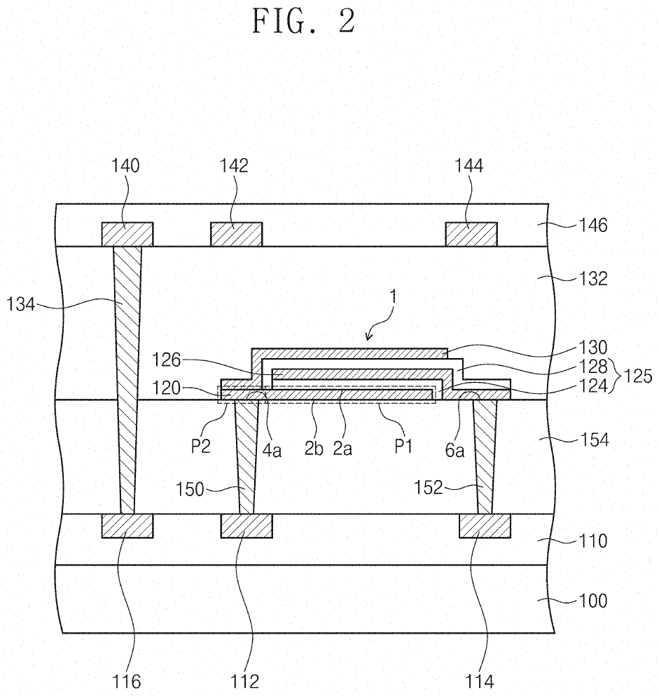

FIG. 2 is a cross-sectional view illustrating a semiconductor device according to some example embodiments of the inventive concepts.

Referring to FIG. 2, a fourth interlayer insulating layer 154 may be disposed between the first interlayer insulating layer 110 and the second interlayer insulating layer 132. The fourth interlayer insulating layer 154 may cover the top surfaces of the first to third lower pads 112, 114 and 116. The fourth interlayer insulating layer 154 may include an insulating material such as a silicon nitride layer, a silicon oxide layer, and/or a silicon oxynitride layer. A second through-via 150 may be disposed in the fourth interlayer insulating layer 154. The second through-via 150 may penetrate the fourth interlayer insulating layer 154 and may be in contact with the first lower pad 112 and/or the bottom surface 2b of the first electrode 120. A top surface 4a of the second through-via 150 may be coplanar with the bottom surface 2b of the first electrode 120 and/or may be located at a level between the top surface 2a and the bottom surface 2b of the first electrode 120. In other words, the second through-via 150 may not penetrate the third electrode 130. The first and/or third electrodes 120 and 130 may be electrically connected to the first lower pad 112 through the second through-via 150. The second through-via 150 may include a conductive material (e.g., tungsten (W), copper (Cu), and/or aluminum (Al)).

A third through-via 152 may be disposed in the fourth interlayer insulating layer 154. The third through-via 152 may penetrate the fourth interlayer insulating layer 154 and may be in contact with the second lower pad 114 and/or a bottom surface of the second electrode 126. A top surface 6a of the third through-via 152 may be coplanar with the bottom surface of the second electrode 126 or may be located at a level between the top surface and the bottom surface of the second electrode 126. The second electrode 126 may be electrically connected to the second lower pad 114 through the third through-via 152. The third through-via 152 may include a conductive material (e.g., tungsten (W), copper (Cu), and/or aluminum (Al)).

The through-via 134 may penetrate the second and/or fourth interlayer insulating layers 132 and 154. The through-via 134 may connect the third lower pad 116 to the first upper pad 140.

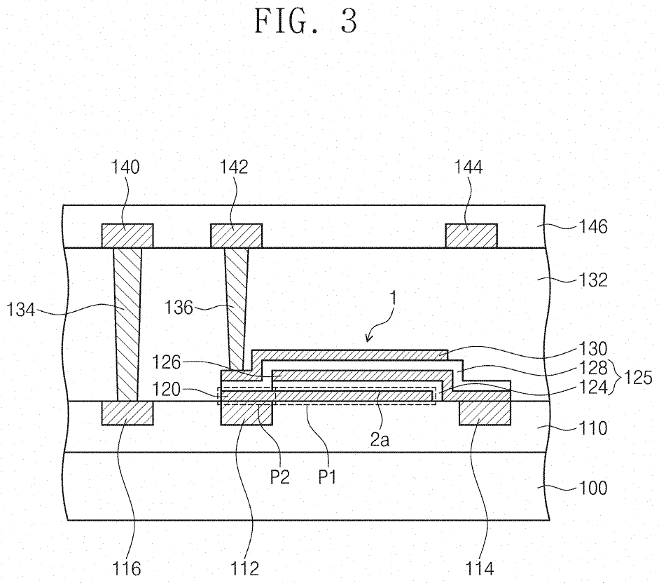

FIG. 3 is a cross-sectional view illustrating a semiconductor device according to some example embodiments of the inventive concepts.

Referring to FIG. 3, the second dielectric portion 128 covering the top surface of the second electrode 126 may extend between the third electrode 130 and the top surface of the second portion P2 of the first electrode 120, which is exposed by the first dielectric portion 124. Thus, the first electrode 120 and the third electrode 130 may not be in physical contact with each other. In other words, the first electrode 120 and the third electrode 130 may be physically spaced apart from each other. The second dielectric portion 128 may cover the top surface of the second portion P2 of the first electrode 120, which is exposed by the first dielectric portion 124. The second dielectric portion 128 may be in contact with the first dielectric portion 124.

A fourth through-via 136 may be disposed in the second interlayer insulating layer 132. The fourth through-via 136 may be disposed on the third electrode 130. The fourth through-via 136 may be in contact with the third electrode 130 and may electrically connect the third electrode 130 to the second upper pad 142. The second upper pad 142 may be in contact with a top surface of the fourth through-via 136. The first lower pad 112 and the third lower pad 116 may be electrically connected to each other. The first upper pad 140 and the second upper pad 142 may be electrically connected to each other. Thus, the first electrode 120 may be electrically connected to the third electrode 130 through the first lower pad 112, the third lower pad 116, the through-via 134, the first upper pad 140, the second upper pad 142, and/or the fourth through-via 136.

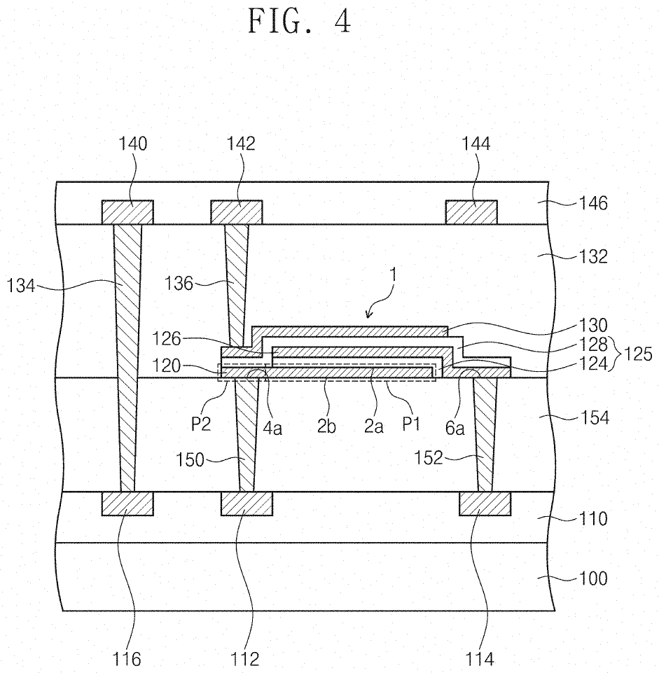

FIG. 4 is a cross-sectional view illustrating a semiconductor device according to some example embodiments of the inventive concepts.

Referring to FIG. 4, the second dielectric portion 128 may extend between the third electrode 130 and the top surface of the second portion P2 of the first electrode 120, which is exposed by the first dielectric portion 124. Thus, the first electrode 120 and the third electrode 130 may not be in physical contact with each other. The fourth interlayer insulating layer 154 may be disposed between the first interlayer insulating layer 110 and the second interlayer insulating layer 132. The second through-via 150 and/or the third through-via 152 may be disposed in the fourth interlayer insulating layer 154. The second through-via 150 and/or the third through-via 152 may penetrate the fourth interlayer insulating layer 154. The second through-via 150 may connect the first lower pad 112 to the first electrode 120. The third through-via 152 may connect the second lower pad 114 to the second electrode 126. The fourth through-via 136 may be disposed in the second interlayer insulating layer 132. The fourth through-via 136 may be disposed between the third electrode 130 and the second upper pad 142. The fourth through-via 136 may electrically connect the third electrode 130 and the second upper pad 142. The first lower pad 112 and the third lower pad 116 may be electrically connected to each other. The first upper pad 140 and the second upper pad 142 may be electrically connected to each other. Thus, the first electrode 120 may be electrically connected to the third electrode 130 through the second through-via 150, the first lower pad 112, the third lower pad 116, the through-via 134, the first upper pad 140, the second upper pad 142, and/or the fourth through-via 136.

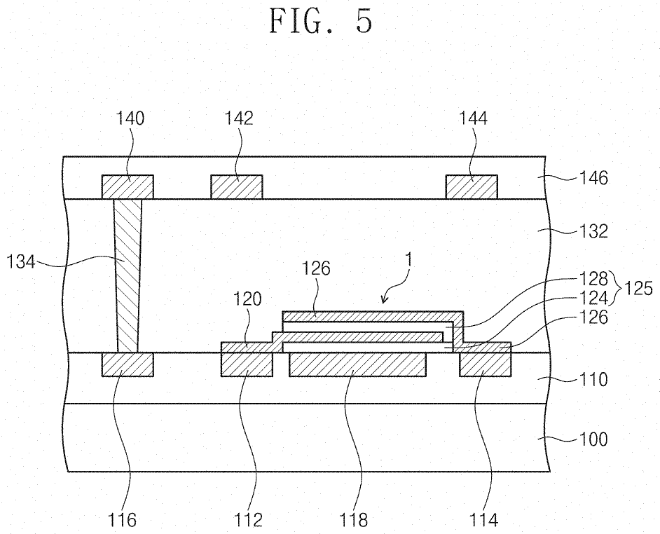

FIG. 5 is a cross-sectional view illustrating a semiconductor device according to some example embodiments of the inventive concepts.

Referring to FIG. 5, the first lower pad 112, the second lower pad 114, the third lower pad 116 and/or a fourth lower pad 118 may be disposed in the first interlayer insulating layer 110. The fourth lower pad 118 may be disposed between the first lower pad 112 and the second lower pad 114. The fourth lower pad 118 may be electrically connected to the second lower pad 114. The fourth lower pad 118 may include, for example, a metal material (e.g., copper, aluminum, and/or tungsten).

A first dielectric portion 124 may cover a top surface of the fourth lower pad 118, which is exposed by the first interlayer insulating layer 110. The first dielectric portion 124 may expose the top surfaces of the first, second and/or third lower pads 112, 114 and 116, which are exposed by the first interlayer insulating layer 110. A first electrode 120 may be disposed on the first dielectric portion 124. The first electrode 120 may cover a top surface and/or a sidewall of the first dielectric portion 124 and/or the top surface of the first lower pad 112. The first electrode 120 may be in contact with the top surface of the first lower pad 112.

A second dielectric portion 128 may be disposed on the first electrode 120. The second dielectric portion 128 may cover a top surface and/or a sidewall of the first electrode 120. The second dielectric portion 128 may extend along the sidewall of the first electrode 120 so as to be in contact with the first dielectric portion 124. Thus, the first dielectric portion 124 and the second dielectric portion 128 may constitute a dielectric layer 125. A second electrode 126 may be disposed on the second dielectric portion 128. The second electrode 126 may cover a top surface and/or a sidewall of the second dielectric portion 128 and/or the top surface of the second lower pad 114. The second electrode 126 may be in contact with the top surface of the second lower pad 114, which is exposed by the first interlayer insulating layer 110. The second electrode 126 may be electrically/physically separated from the first electrode 120.

According to some example embodiments of the inventive concepts, a capacitor 1 may include the first electrode 120, the dielectric layer 125, the second electrode 126, and/or the fourth lower pad 118. The fourth lower pad 118 may function as a third electrode of the capacitor 1. In other words, the fourth lower pad 118 may be one of three electrodes of the capacitor 1, which is electrically connected to the second electrode 126 through the second lower pad 114.

FIG. 6 is a cross-sectional view illustrating a semiconductor device according to some example embodiments of the inventive concepts.

Referring to FIG. 6, the fourth lower pad 118 described with reference to FIG. 5 may be omitted. In this case, the second lower pad 114 may extend under the first dielectric portion 124 to overlap with the first electrode 120. Thus, the second lower pad 114 may function as a connection pad for connecting the second electrode 126 to one of the second and third upper pads 142 and 144 and may also function as one of electrodes of the capacitor 1. The second electrode 126 may be in contact with the top surface of the second lower pad 114, which is exposed by the first and/or second dielectric portions 124 and 128. Thus, the second electrode 126 and the second lower pad 114 may be electrically connected to each other.

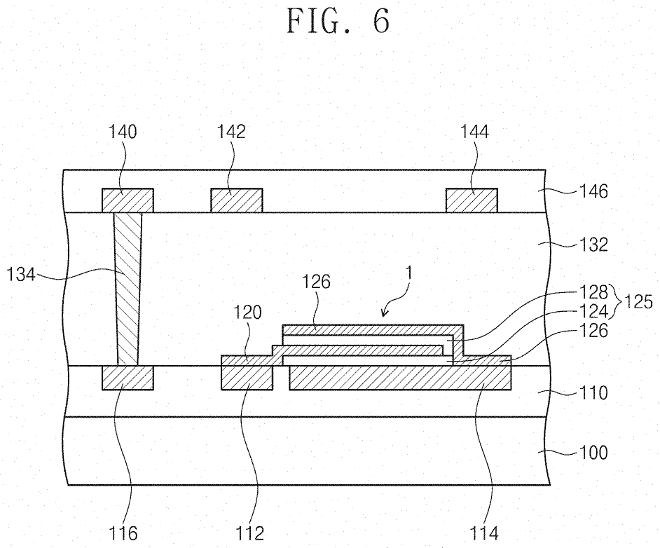

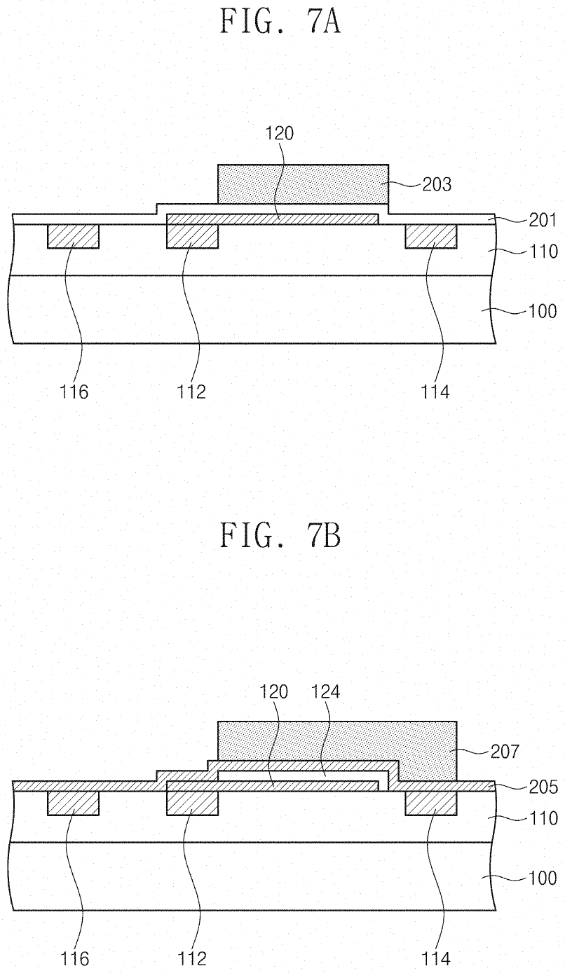

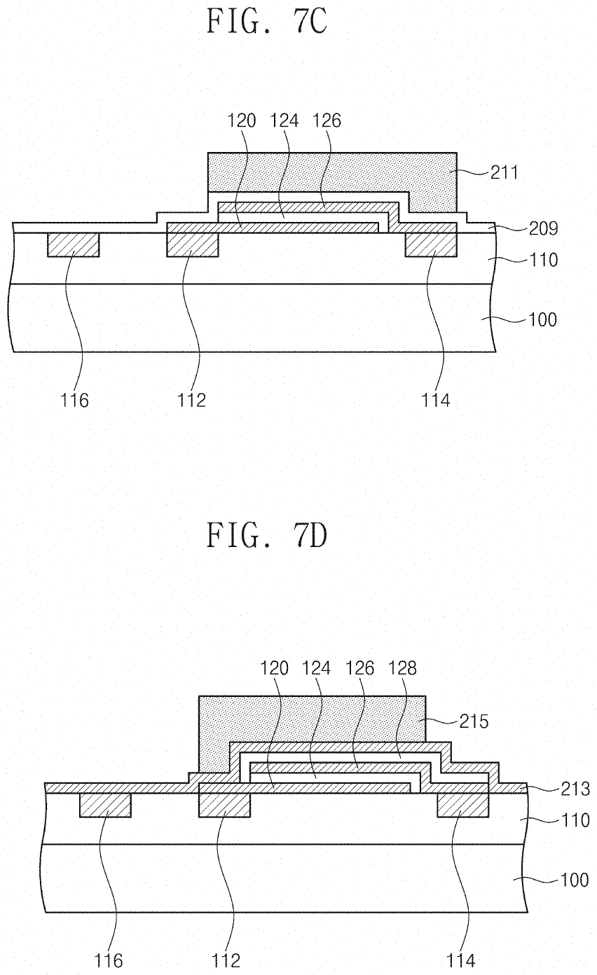

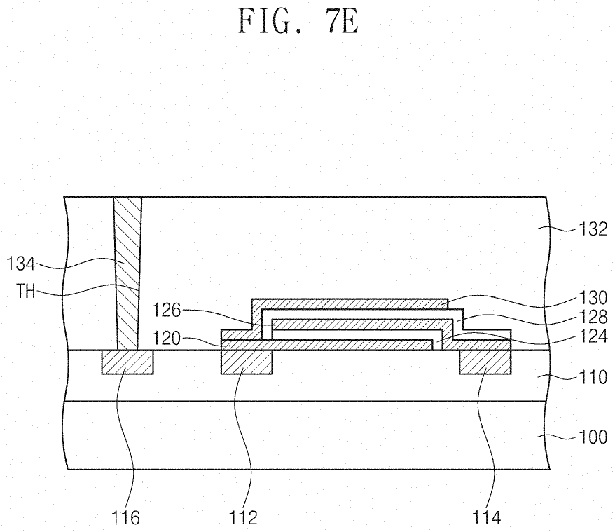

FIGS. 7A to 7E are cross-sectional views illustrating a method of manufacturing a semiconductor device, according to some example embodiments of the inventive concepts.

Referring to FIG. 7A, a first interlayer insulating layer 110 may be formed on a substrate 100. A first lower pad 112, a second lower pad 114 and/or a third lower pad 116 may be disposed in the first interlayer insulating layer 110. Top surfaces of the first to third lower pads 112, 114 and 116 may be exposed by the first interlayer insulating layer 110. A first electrode 120 may be formed on the first interlayer insulating layer 110. A first electrode layer (not shown) may be formed to cover a top surface of the first interlayer insulating layer 110 and/or the top surfaces of the first to third lower pads 112, 114 and 116, and/or a patterning process may be performed on the first electrode layer to form the first electrode 120. The first electrode 120 may cover the top surface of the first lower pad 112 and may expose the top surfaces of the second and third lower pads 114 and 116. The patterning process may be performed using a wet etching process or a dry etching process.

A first dielectric layer 201 may be formed on the first interlayer insulating layer 110. The first dielectric layer 201 may be formed to conformally cover a top surface and/or sidewalls of the first electrode 120, the top surface of the first interlayer insulating layer 110, and/or the top surfaces of the second and/or third lower pads 114 and 116. For example, the first dielectric layer 201 may include at least one of Si₃N₄, Ta₂O₅, Al₂O₃, and/or ZrO₂.

A first mask pattern 203 may be formed on the first dielectric layer 201. The first mask pattern 203 may be formed to overlap with the first electrode 120. The first mask pattern 203 may be formed to expose a top surface of the first dielectric layer 201 covering the top surfaces of the first to third lower pads 112, 114 and 116. The first mask pattern 203 may include, for example, a photoresist pattern.

Referring to FIG. 7B, the first dielectric layer 201 may be etched using the first mask pattern 203 as an etch mask. Thus, a first dielectric portion 124 may be formed on the first electrode 120. The first dielectric portion 124 may be formed to cover a portion of the top surface of the first electrode 120 and/or a sidewall of the first electrode 120. The first dielectric portion 124 may expose the top surfaces of the first to third lower pads 112, 114 and 116 and/or the top surface of the first interlayer insulating layer 110. For example, the etching process may be performed using a wet etching process or a dry etching process. The first mask pattern 203 may be removed after the etching process. Thus, a top surface of the first dielectric portion 124 may be exposed. For example, the removal process may be performed by an ashing process and/or a strip process.

A second electrode layer 205 may be formed on the first dielectric portion 124. The second electrode layer 205 may conformally cover the top surface and/or sidewalls of the first dielectric portion 124, surfaces (e.g., another portion of the top surface and/or other sidewall) of the first electrode 120 exposed by the first dielectric portion 124, the top surface of the first interlayer insulating layer 110, and/or the top surfaces of the second and/or third lower pads 114 and 116. For example, the second electrode layer 205 may include at least one of TaN, Ta, Al, Ti, TiN, TaSiN, WN, and/or WSiN.

A second mask pattern 207 may be formed on the second electrode layer 205. The second mask pattern 207 may cover a portion of a top surface of the second electrode layer 205 and/or a sidewall of the second electrode layer 205. The second mask pattern 207 may overlap with the second lower pad 114. The second mask pattern 207 may include, for example, a photoresist pattern.

Referring to FIG. 7C, the second electrode layer 205 may be etched using the second mask pattern 207 as an etch mask. Thus, a second electrode 126 may be formed on the first dielectric portion 124. The second electrode 126 may be formed to conformally cover the top surface and/or a sidewall of the first dielectric portion 124, a portion of the top surface of the first interlayer insulating layer 110, and/or the top surface of the second lower pad 114. The second electrode 126 may expose the portion of the top surface of the first electrode 120 exposed by the first dielectric portion 124, and/or the top surface of the third lower pad 116. For example, the etching process may be performed using a wet etching process or a dry etching process. After the etching process, the second mask pattern 207 may be removed by an ashing process and/or a strip process.

A second dielectric layer 209 may be formed on the second electrode 126. The second dielectric layer 209 may conformally cover a top surface and/or sidewalls of the second electrode 126, the top surface of the first interlayer insulating layer 110, a portion of the top surface of the first electrode 120 exposed by the first dielectric portion 124, and/or the top surface of the third lower pad 116. For example, the second dielectric layer 209 may include at least one of Si₃N₄, Ta₂O₅, Al₂O₃, and/or ZrO₂.

A third mask pattern 211 may be formed on the second dielectric layer 209. The third mask pattern 211 may cover a portion of a top surface of the second dielectric layer 209 and/or a sidewall of the second dielectric layer 209. The third mask pattern 211 may overlap with the second lower pad 114. The third mask pattern 211 may include, for example, a photoresist pattern.

Referring to FIG. 7D, the second dielectric layer 209 may be etched using the third mask pattern 211 as an etch mask. Thus, a second dielectric portion 128 may be formed on the second electrode 126. The second dielectric portion 128 may cover the top surface and/or sidewalls of the second electrode 126. The second dielectric portion 128 may be in contact with an end of the first dielectric portion 124 on the top surface of the first electrode 120. The second dielectric portion 128 may expose a portion of the top surface of the first electrode 120 being in contact with the first lower pad 112, the top surface of the first interlayer insulating layer 110, and/or the top surface of the third lower pad 116. The etching process may be performed using a wet etching process or a dry etching process. After the etching process, the third mask pattern 211 may be removed by an ashing process and/or a strip process.

A third electrode layer 213 may be formed on the second dielectric portion 128. The third electrode layer 213 may be formed to conformally cover a top surface and sidewalls of the second dielectric portion 128, the portion of the top surface of the first electrode 120 exposed by the second dielectric portion 128, a sidewall of the second electrode 126, the top surface of the first interlayer insulating layer 110, and/or the top surface of the third lower pad 116. For example, the third electrode layer 213 may include at least one of TaN, Ta, Al, Ti, TiN, TaSiN, WN, and/or WSiN.

A fourth mask pattern 215 may be formed on the third electrode layer 213. The fourth mask pattern 215 may cover a portion of a top surface of the third electrode layer 213 and/or a sidewall of the third electrode layer 213. The fourth mask pattern 215 may overlap with the first lower pad 112. The fourth mask pattern 215 may include, for example, a photoresist pattern.

Referring to FIG. 7E, the third electrode layer 213 may be etched using the fourth mask pattern 215 as an etch mask. Thus, a third electrode 130 may be formed on the second dielectric portion 128 and/or a portion of the top surface of the first electrode 120. The third electrode 130 may cover a portion of the top surface and/or a sidewall of the second dielectric portion 128, and/or the portion of the top surface of the first electrode 120 exposed by the second dielectric portion 128. The third electrode 130 may expose the top surface of the first interlayer insulating layer 110 and/or the top surface of the third lower pad 116. The etching process may be performed using a wet etching process or a dry etching process. After the etching process, the fourth mask pattern 215 may be removed by an ashing process and/or a strip process.

A second interlayer insulating layer 132 may be formed on the first interlayer insulating layer 110. The second interlayer insulating layer 132 may cover the first to third electrodes 120, 126 and 130, the second dielectric portion 128, the first dielectric portion 124, the first interlayer insulating layer 110, and/or the third lower pad 116.

A through-via 134 may be formed in the second interlayer insulating layer 132. The formation of the through-via 134 may include forming a through-hole TH exposing the top surface of the third lower pad 116 in the second interlayer insulating layer 132, forming a metal layer (not shown) filling the through-hole TH and covering a top surface of the second interlayer insulating layer 132, and/or performing a planarization process on the metal layer to expose the top surface of the second interlayer insulating layer 132. The through-via 134 may be in contact with the third lower pad 116.

Referring again to FIG. 1, first, second and/or third upper pads 140, 142 and 144 may be formed on the second interlayer insulating layer 132. The first upper pad 140 may be formed on a top surface of the through-via 134. The second and/or third upper pads 142 and 144 may be formed on the top surface of the second interlayer insulating layer 132. A pad layer (not shown) may be formed on the top surface of the second interlayer insulating layer 132, and/or a patterning process may be performed on the pad layer to form the first to third upper pads 140, 142 and 144. In some example embodiments, the first to third upper pads 140, 142 and 144 may be spaced apart from each other.

A third interlayer insulating layer 146 may be formed on the second interlayer insulating layer 132. The third interlayer insulating layer 146 may cover the top surface of the second interlayer insulating layer 132 and the first to third upper pads 140, 142 and 144.

According to some example embodiments of the inventive concepts, the first electrode may be in direct contact with the first lower pad, and the second electrode may be in direct contact with the second lower pad. Thus, it is possible to omit a process of forming through-vias for connecting the first and second electrodes to the first and second lower pads, respectively. As a result, processes of manufacturing the semiconductor device may be simplified. In addition, since the first and second electrodes are in direct contact with the first and second lower pads, respectively, resistances may be reduced. As a result, the electrical characteristics of the semiconductor device may be improved.

While the inventive concepts have been described with reference to some example embodiments, it will be apparent to those skilled in the art that various changes and modifications may be made without departing from the spirits and scopes of the inventive concepts. Therefore, it should be understood that the above example embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. A semiconductor device comprising:
a first lower pad and a second lower pad on a substrate;
a first electrode in contact with a top surface of the first lower pad;
a second electrode on the first electrode, the second electrode in contact with a top surface of the second lower pad;
a dielectric layer between the first electrode and the second electrode; and
a third electrode on the second electrode.

2. The semiconductor device of claim 1, wherein a portion of a bottom surface of the second electrode is substantially coplanar with a bottom surface of the first electrode.

3. The semiconductor device of claim 1, further comprising:
a via on the third electrode and connected to the third electrode; and
an upper pad in contact with a top surface of the via.

4. The semiconductor device of claim 1, wherein,
the dielectric layer covers a portion of a top surface of the first electrode, and
a portion of the third electrode is connected to another portion of the top surface of the first electrode.

5. The semiconductor device of claim 1, wherein the dielectric layer includes a first dielectric portion and a second dielectric portion, wherein,
the first dielectric portion is between the first electrode and the second electrode, and
the second dielectric portion covers a sidewall of the second electrode and is between the second electrode and the third electrode.

6. The semiconductor device of claim 1, wherein
the dielectric layer covers a top surface of the first electrode, and
the third electrode is spaced apart from the first electrode.

7. The semiconductor device of claim 1, further comprising:
a third lower pad on the substrate;
a via on the third lower pad and connected to the third lower pad; and
an upper pad on the via and connected to the via,
wherein the first lower pad is electrically connected to the third lower pad.

8. A semiconductor device comprising:
a first lower pad and a second lower pad on a substrate;
a first electrode on the first lower pad and connected to the first lower pad;
a second electrode on the first electrode and connected to a top surface of the second lower pad;
a first dielectric layer between the first electrode and the second electrode;
a second dielectric layer on the second electrode; and
a third electrode on the second dielectric layer and in contact with a top surface of the first electrode.

9. The semiconductor device of claim 8, wherein a portion of a bottom surface of the second electrode is substantially coplanar with a bottom surface of the first electrode.

10. The semiconductor device of claim 8, wherein,
the first electrode is in contact with a top surface of the first lower pad, and
the second electrode is in contact with the top surface of the second lower pad.

11. The semiconductor device of claim 8, further comprising:
a first via between the first electrode and the first lower pad, the first via in contact with a bottom surface of the first electrode; and
a second via between the second electrode and the second lower pad, the second via in contact with a bottom surface of the second electrode.

12. The semiconductor device of claim 8, further comprising:
a third lower pad on the substrate;
a via on the third lower pad and connected to the third lower pad; and
an upper pad on the via and connected to the via,
wherein the first lower pad is electrically connected to the third lower pad.

13. The semiconductor device of claim 8, wherein the first dielectric layer and the second dielectric layer are connected to each other on a top surface of the first electrode.

14. A semiconductor device comprising:
a first pad and a second pad on a substrate;
a first insulating layer on the first pad and the second pad;
a first electrode on the first insulating layer;
a first through-via penetrating the first insulating layer and electrically connecting a bottom surface of the first electrode and a top surface of the first pad;
a second electrode on the first electrode;
a second through-via penetrating the first insulating layer and electrically connecting a bottom surface of the second electrode and a top surface of the second pad;
a first dielectric layer between the first electrode and the second electrode;
a second dielectric layer on the second electrode; and
a third electrode on the second dielectric layer.

15. The semiconductor device of claim 14, wherein,
the third electrode contacts a portion of a top surface of the first electrode, and
the portion of the top surface of the first electrode is exposed by the first and second dielectric layers.

16. The semiconductor device of claim 14, further comprising:
a second insulating layer on the third electrode;
a third through-via penetrating the second insulating layer and contacting a top surface of the third electrode; and
a third pad on the third through-via.

17. The semiconductor device of claim 14, wherein a top surface of the first through-via is coplanar with the bottom surface of the first electrode or is at a level between a top surface and the bottom surface of the first electrode.

18. The semiconductor device of claim 14, wherein a top surface of the second through-via is coplanar with the bottom surface of the second electrode or is at a level between a top surface and the bottom surface of the second electrode.

19. The semiconductor device of claim 14, wherein the first electrode is electrically connected to the third electrode.

20. The semiconductor device of claim 14, wherein the second dielectric layer is between the first electrode and the third electrode such that the first electrode and the third electrode are physically spaced apart from each other.
